(19) United States
(12) Patent Application Publication
(10) Pub. No.: US 2005/0233224 A1
(43) Pub. Date: Oct. 20, 2005

(54) Method of improving polysilicon film crystallinity

(75) Inventors: Chang-Ho Tseng, Sinwu Township (TW); Shih-Chang Chang, Hsinchu (TW); Yaw-Ming Tsai, Taichung Hsien (TW); Yu-Ting Hung, Sinying City (TW); Ryan Lee, Hualien City (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 10/941,720

(22) Filed: Sep. 15, 2004

(30) Foreign Application Priority Data
Apr. 20, 2004 (TW) 93110931

(51) Int. Cl. H01J 37/08; G21K 5/10; H01L 31/036; G03B 21/56; H01L 29/10; H01L 29/04; G03F 9/00; G02B 5/08; G02B 7/182

(52) U.S. Cl. 430/5; 257/64; 250/492.22; 359/443; 359/883

(57) ABSTRACT

A method of improving a polysilicon film crystallinity in a sequential lateral solidification process is provided. A mask having a main pattern portion and a compensating pattern portion is provided. The main pattern portion defines a laser beam pattern scanning and transforming an amorphous silicon film into a polysilicon film. The compensating pattern portion adjacent to the main pattern portion adjusts the energy of the laser beam injected to the polysilicon film to improve the grain shape thereof.

### BACKGROUND OF THE INVENTION

1. Field of the Invention The invention relates to a laser annealing, and more particularly to an additional laser annealing procedure subsequent to a sequential lateral solidification (SLS) process for improving the grain shape of a polysilicon film.

2. Description of the Related Art

Thin film transistors (TFTs) are commonly employed as an active element of an active matrix flat panel display, and are often utilized as a driving element for an active matrix type liquid crystal display.

A low temperature polysilicon film is used more often than an amorphous silicon (a-Si:H) film in TFTs due to its excellent electric conductivity and field mobility thereof.

A polysilicon film fabrication method comprises an exposure of an amorphous silicon film to an excimer laser annealing (ELA), causing recrystallization and forming a polysilicon film. The excimer laser annealing, however, is implemented in a scan speed of only 0.6 cm/sec, and an energy of 370 mJ/cm², hence, and the grain size is less than 0.5 μm.

Recently a sequential lateral solidification (SLS) process with a high scan speed (30 cm/sec) and a high laser energy (600 mJ/cm²) has been utilized as a method for forming the polysilicon film, wherein the shape of a laser beam employed by the SLS is defined by a patterned mask and the laser beam continuously anneals each section of the amorphous silicon film.

In FIG. 1, a conventional mask having a first pattern 10a and a complementary pattern 10b for defining the shape of the laser beam is a 2-shot mask, each comprising opening portions 101 and spacer portions 102 to partially block the laser beam. The mask moves in a direction indicated by the arrow in FIG. 1.

The laser beam defined by the first pattern 10a and the complementary pattern 10b are sequentially scan a predetermined region of the amorphous silicon film. The laser beam anneals and recrystallizes the predetermined region to form a polysilicon film, with the grain size of 2-5 μm. After the entire amorphous silicon film is recrystallized, the polysilicon film has some tiny grains 201 in the multi-irradiated region as shown in FIG. 2.

### SUMMARY OF THE INVENTION

The present invention is directed to a mask and a method to improve the crystallinity of a polysilicon film that suffer a laser annealing under a sequential lateral solidification process.

Basically, the present invention provides a mask used for a recrystallization of a polysilicon film in a sequential lateral solidification (SLS) process, comprising a main pattern portion for defining a pattern of a laser beam that scans and transforms an amorphous silicon film into a polysilicon film, and a compensating pattern portion adjacent to the main pattern portion for adjusting the energy of the laser beam so as to improve grain shape thereof.

ccMoreover, the present invention provides a method for improving a crystallinity of a polysilicon film in a sequential lateral solidification (SLS) process. An amorphous silicon film is first provided. A mask having a main pattern portion and a compensating pattern portion is then provided, wherein the compensating pattern portion is adjacent to the main pattern portion. A laser beam scans and transforms a predetermined region of the amorphous silicon film into a polysilicon film through the main pattern portion. The laser beam irradiates the predetermined region of the polysilicon film through the compensating pattern portion to improve grain shape thereof.

Accordingly, the present invention also provides a method for improving the crystallinity of the polysilicon film in a sequential lateral solidification (SLS) process. An amorphous silicon film is provided. A mask is provided first. The mask is used for the sequential lateral solidification process to transform the amorphous silicon film into a polysilicon film. The polysilicon film is fully annealed so as to improve grain shape thereof.

### BRIEF DESCRIPTION OF THE DRAWINGS

For a better understanding of the present invention, reference is made to a detailed description to be read in conjunction with the accompanying drawings, in which:

FIG. 1 shows a conventional laser annealing mask for a sequential lateral solidification process;

FIG. 2 is a top view of a polysilicon film with tiny crystals;

FIG. 3 shows a laser annealing mask according to one embodiment of the present invention for a sequential lateral solidification;

FIG. 4 shows another laser annealing mask according to one embodiment of the present invention for a sequential lateral solidification;

FIG. 5 shows another laser annealing mask according to one embodiment of the present invention for a sequential lateral solidification process;

FIG. 6 shows another laser annealing mask according to one embodiment of the present invention for a sequential lateral solidification;

FIG. 7 is a top view of a polysilicon film after performing an overall laser annealing;

FIG. 8 is a flowchart of the method for improving the crystallinity of the polysilicon film by a sequential lateral solidification process;

FIG. 9 is a flowchart of a method according to one embodiment of the present invention for forming a polysilicon film by SLS and ELA.

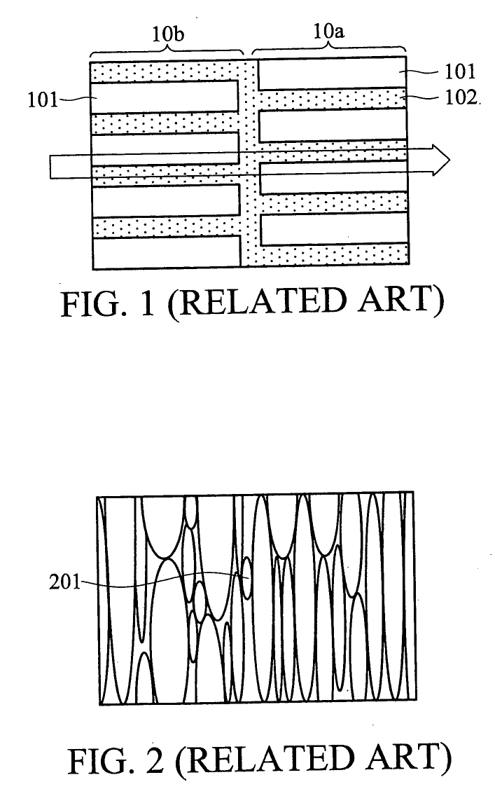

### DETAILED DESCRIPTION OF THE INVENTION

In order to form a high quality polysilicon film without tiny crystals, the present invention provides an additional laser annealing to the entire polysilicon film.

### First Embodiment

The first method according to this invention for fully annealing the polysilicon film is to modify the pattern of a mask.

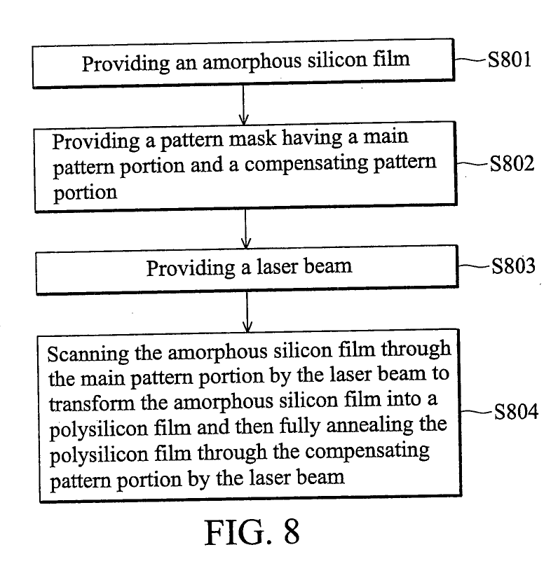

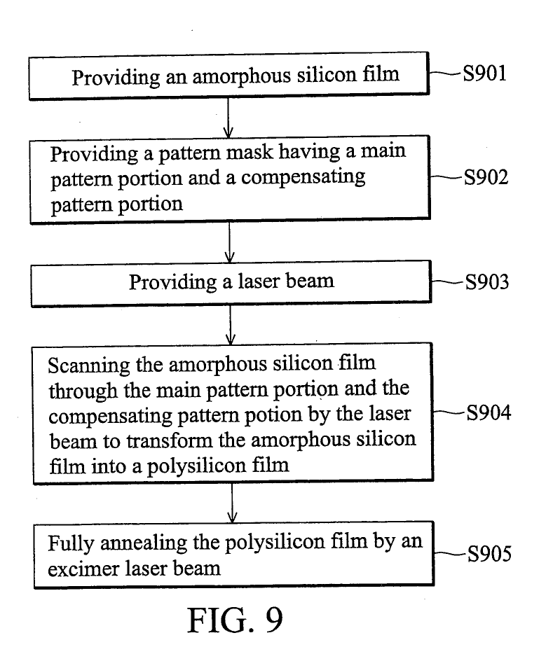

A flowchart of the method for improving the crystallinity of a polysilicon film by a sequential lateral solidification process is shown in FIG. 8.

In Step S801, a glass substrate with an amorphous silicon film formed thereon is provided.

In Step S802, a mask with a main pattern portion and a compensating pattern portion is provided. The main pattern portion having opening portions and spacer portions is a 2-shot mask or 1-shot mask, and the width of each opening portion is larger than that of each spacer portion. The pattern of the compensating pattern portion can be a transparent pattern, a translucent pattern, or a dummy pattern, wherein the shape of the translucent pattern or dummy pattern is arbitrary. The line width of the translucent or dummy pattern, however, is not great enough to be analyzed by the SLS laser machine for imaging on the polysilicon film, hence, the energy of the laser beam injected to the polysilicon film is through the compensating portion reduced thereafter.

In Step S803, a laser beam, such as a semi-Gaussian beam or a flat-top shape beam with a laser energy of 600 mJ/cm² is provided. The region of the flat-top shape beam is larger than the predetermined region.

In step S804, the laser beam scans the amorphous silicon film through the main pattern portion to transform the amorphous silicon film into a polysilicon film.

The laser beam scans and fully anneals the polysilicon film through the compensating pattern portion. The area ratio of the laser beam through the compensating pattern portion to that through the main pattern portion is ⅓ to ⅗, the intensity of the laser beam is below a full melt threshold intensity: 370 mJ/cm² of the polysilicon film, and the laser beam used to scan the polycrystalline silicon film is overlapped on scan pitch.

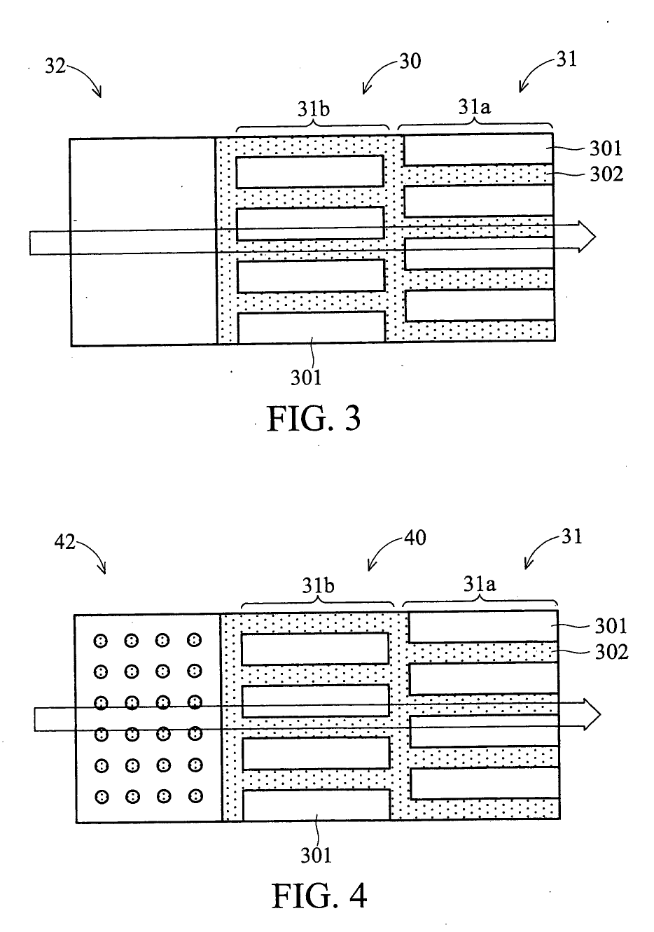

In one embodiment, a laser annealing mask used in a sequential lateral solidification (SLS) process is provided as shown in FIG. 3.

The mask 30 according to this embodiment comprises a main pattern portion 31 and a compensating pattern portion 32. The main pattern portion 31 having a first pattern 31a and a complementary pattern 31b is a 2-shot mask, each of which has opening portions 301 and spacer portions 302 to partially block the laser formed thereon. The mask 30 moves in a direction indicated by the arrow in FIG. 3. The compensating pattern portion 32 is transparent, and the laser beam scans the amorphous silicon film therethrough.

The laser beam defined by the main pattern 31a and the complementary pattern 31b sequentially scans a predetermined region of the amorphous silicon film. The laser beam fully irradiates and thus anneals and recrystallizes the amorphous silicon film forming a polysilicon film. After the amorphous silicon film is recrystallized by the above procedure, the produced polysilicon film has some tiny grains in the multi-irradiating region as shown in FIG. 2.

Next, the polysilicon film is fully irradiated by the laser beam defined by the compensating pattern portion 32 to be further annealed and recrystallized, increasing the temperature thereof, and the tiny grains therein are melted and integrated with larger grains as shown in FIG. 7.

In another embodiment, another laser annealing mask for a sequential lateral solidification (SLS) process is provided as shown in FIG. 4.

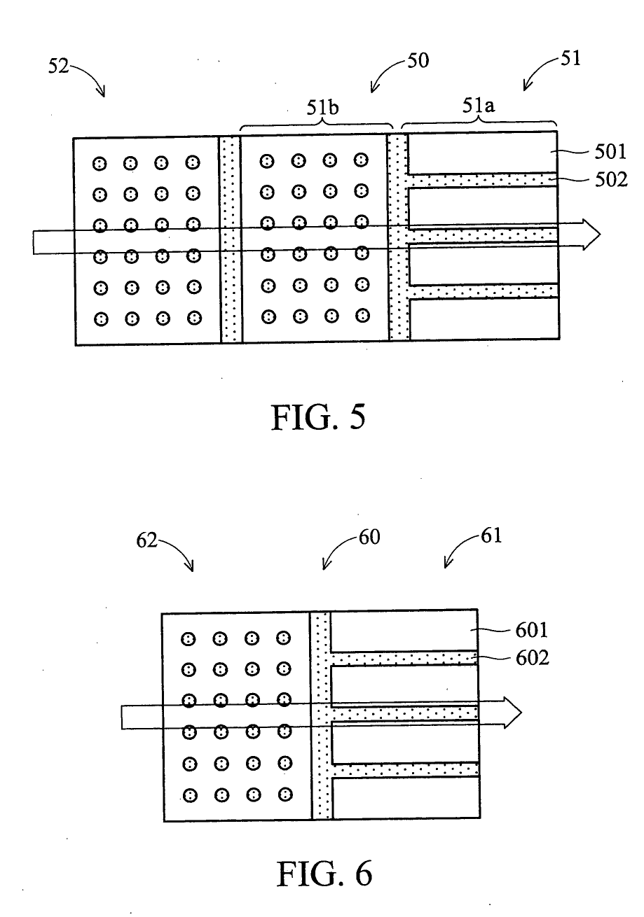

The mask 40 according to this embodiment comprises the same main pattern portion 31 as shown in FIG. 3 and a compensating pattern portion 42. The compensating pattern portion 42 is a translucent pattern or a dummy pattern, and the energy of the laser beam is adjusted according to that pattern. The mask 40 moves in a direction indicated by the arrow in FIG. 4. The line width of the translucent or dummy pattern, however, is not great enough to be analyzed by the SLS laser machine to generate image on the polysilicon film. In another embodiment, another laser annealing mask for a sequential lateral solidification (SLS) process is provided as shown in FIG. 5.

The mask 50 according to this embodiment comprises a main pattern portion 51 and a compensating pattern portion 52. The main pattern portion 51 has a first pattern 51a and a second pattern 51b, and the first pattern 51a has opening portions 501 and spacer portions 502 to partially block the laser beam. The mask 50 moves in a direction indicated by the arrow in FIG. 5. The width of each spacer portion 502 is smaller than that of the spacer portion 302 as shown in FIGS. 3 and 4, and the area ratio of the spacer portion 502 to the opening portion 501 is ⅓. The second pattern 51b is a translucent pattern or dummy pattern. The compensating pattern portion 52 is the same as the compensating pattern portion shown in FIG. 3 or 4 and is a transparent pattern, translucent pattern, or dummy pattern. The energy of the laser beam irradiated to the amorphous silicon film through the compensating pattern portion 52 is reduced or not.

The laser beam defined by the first pattern 51a and the complementary pattern 51b sequentially scans a predetermined region of the amorphous silicon film. The laser beam irradiates the predetermined region and thus anneals and recrystallizes the amorphous silicon film into a polysilicon film.

Next, the polysilicon film is fully irradiated by the laser beam defined by the compensating portion 52 to be further annealed and recrystallized, increasing the temperature thereof, and the tiny grains therein are melted and integrated with larger grains

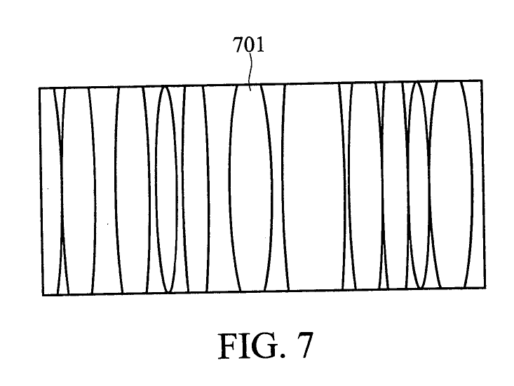

In further embodiment, another laser annealing mask for a sequential lateral solidification (SLS) process is provided as shown in FIG. 6.

The mask 60 according to this embodiment comprises a main pattern portion 61 and a compensating pattern portion 62. The mask 60 moves in the direction indicated by the arrow in FIG. 6. The main pattern portion 61 is a 1-shot mask, and opening portions 601 and spacer portions 602 are formed thereon. A width of the spacer portion 601 is smaller than that of the opening portion 601. The area ratio of the spacer portions 602 to the opening portions 601 is ⅓.

The compensating pattern portion 62 is the same as the compensating pattern portion 52 shown in FIG. 5 and could be a transparent pattern, a translucent pattern, or a dummy pattern. The energy of the laser beam irradiated to the amorphous silicon film through the compensating pattern portion 62 is reduced or not.

After the amorphous silicon film is irradiated by the laser beam defined by the main pattern portion 61, and the laser beam through the compensating pattern portion 62 irradiates the number of tiny grains in the produced polysilicon film is reduced.

### Second Embodiment

A second method according to this invention for fully annealing the polysilicon film is to combine an SLS process and an ELA process.

The method for forming a polysilicon film by the SLS process and the ELA process is described below.

In step S901, a glass substrate with an amorphous silicon film formed thereon is provided.

In step S902, a mask having a main pattern portion and a compensating pattern portion is provided. The main pattern portion having opening portions and spacer portions is a 2-shot mask or 1-shot mask, and the area ratio of the spacer portions to the opening portions is ⅓.

In step S903, a laser beam is provided, wherein the laser beam can be a semi-Gaussian beam or a flat top shaped beam.

In step S904, the laser beam scans the amorphous silicon film through the main pattern portion and the compensating pattern potion to transform the amorphous silicon film into a polysilicon film.

In step S905, the polysilicon film is fully annealed by an excimer laser, and a scanning speed thereof is 0.6 cm/sec and the energy thereof is 370 mJ/cm².

After the polysilicon film is fully annealed by the excimer laser, the temperature thereof is increased, and the tiny grains are melted and integrated with the larger grains.

Both methods of the present invention provide an additional full annealing step after the SLS process, the tiny grains are melted and integrated with the larger grains, and therefore the number of the tiny grains is reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A mask for recrystallization in a sequential lateral solidification (SLS) process comprising:
a main pattern portion to define a pattern of a laser beam scanning the amorphous silicon film to transform the amorphous silicon film into a polysilicon film; and
a compensating pattern portion adjacent to the main pattern portion for adjusting the energy of the laser beam scanning the polysilicon film to improve grain shape thereof.

2. The mask of claim 1, wherein the compensating pattern portion is transparent.

3. The mask of claim 1, wherein the compensating pattern portion is translucent.

4. The mask of claim 1, wherein the compensating pattern portion comprises a dummy pattern.

5. The mask of claim 1, wherein the energy ratio of the laser beam adjusted by the compensating pattern portion to that through the main pattern portion is ⅓˜⅗.

6. A method for improving polysilicon film crystallinity in a sequential lateral solidification (SLS) process, comprising:
providing an amorphous silicon film;
providing a mask having a main pattern portion and a compensating pattern portion, wherein the compensating pattern portion is adjacent to the main pattern potion;
providing a laser beam to scan a predetermined region of the amorphous silicon film through the main pattern portion to transform the amorphous silicon film into a polysilicon film; and
irradiating the laser beam to the predetermined region of the polysilicon film through the compensating pattern portion.

7. The method of claim 6, wherein the compensating pattern portion is transparent.

8. The method of claim 6, wherein the compensating pattern portion is translucent.

9. The method of claim 6, wherein the compensating pattern portion comprises a dummy pattern.

10. The method of claim 6, wherein the laser beam is a semi-Gaussuan beam.

11. The method of claim 6, wherein the laser beam is a flat-top shaped beam.

12. The method of claim 6, wherein the intensity of the laser beam is 600 mJ/cm².

13. The method of claim 6, wherein the energy ratio of the laser beam through the compensating pattern portion to that through the main pattern portion is ⅓ to ⅗.

14. The method of claim 6, wherein the intensity of the laser beam is below a full melt threshold intensity: 370 mJ/cm² of the polysilicon film.

15. A method for improving polysilicon film crystallinity in a sequential lateral solidification (SLS) process, comprising:
providing an amorphous silicon film;
providing a mask;
using the mask in a sequential lateral solidification process to transform the amorphous silicon film into a polysilicon film; and
fully annealing the polysilicon film.

16. The method of claim 15, wherein the step for fully annealing the polysilicon film utilizes an excimer laser annealing process.

17. The method of claim 15, wherein a scanning speed of the mask through the amorphous silicon film is 0.6 cm/sec and the energy of the laser beam used in the scanning is 370 mJ/cm².

18. The method of claim 15, the method for fully annealing further comprising steps of:
providing a compensating mask; and
irradiating a laser beam through the compensating mask to the polysilicon film.
